(19) United States
(12) Patent Application Publication
(10) Pub. No.: US 2003/0158711 A1
(43) Pub. Date: Aug. 21, 2003

(54) Method for automatically releasing and placing an order

(76) Inventors: Frank Buerger, Overath (DE); Frank Weinert, Koln (DE)

Correspondence Address: Friedrich Kueffner, Suite 910, 317 Madison Avenue, New York, NY, 10017, US

(21) Appl. No.: 10/311,393

(22) PCT Filed: May 30, 2001
(86) PCT No.: PCT/EP01/06120

(30) Foreign Application Priority Data
Jun. 13, 2000 (EP) 00112504.6

(51) Int. Cl. H03F 1/26; G06F 15/00; H04B 15/00

(52) U.S. Cl. 702/189

(57) ABSTRACT

The invention relates to a method for the automatic release and placement of orders by means of data communications devices, data concentration devices and telecommunication devices.

The present invention relates to a method for automatic order release and placing of orders by means of data communications devices, data concentration devices and telecommunications devices.

The volume of commercial transactions handled through the World Wide Web services is growing dramatically, especially in the business-to-business area. These transactions are generally executed in virtual marketplaces. To act successfully in these marketplaces, the buyer often has to make very rapid purchase decisions, which because of the lack of time are usually not based on an objective evaluation, especially as in the case of special products he usually has no rival bids on hand.

The present invention is therefore based on the object of supplying a method for automatic order release.

The object is achieved according to the invention with a method for automated order release by means of data communications devices, telecommunications networks and at least one data concentration device, the method presenting any number of repetitions of the following procedural steps:

a) Transmission of a bid with data relating to the bid, by means of a data communications device over a telecommunications network to a data concentration device,

b) Evaluation, in the data concentration device, of the bid-related data transmitted in step a), using the data available there and at least one checking criterion,

whereupon in the case of a positive evaluation:

bb1) the order release follows in the form of a release code referencing the particular bid,

bb2) the transmitted data is transferred into the available data in the data concentration device, according to a data acquisition process,

bb3) the release code is transmitted from the data concentration device over a telecommunications network to the buyer's data communications device,

and whereupon in the case of a negative evaluation:

bb4) the transmitted data is transferred into the available data in the data concentration device, according to a data acquisition process,

bb5) a fake code is optionally sent from the data concentration device over the telecommunications network to the buyer's data communications device.

A data communications device in the sense of the invention is any data terminal that has, among others, HTML (HyperText Markup Language) capability; preferably a standard personal computer. On to this data communications device are loaded e.g. home pages from a buyer's server, containing the bid invitation for a particular product. The desired product is specified in detail in the bid invitation, and the bid-related data to be presented by the seller when submitting a bid is also precisely stated. The seller's bid with the bid-related data is also transmitted to the data concentration device from this terminal.

A data concentration, device in the sense of the invention is any single database computer, or a computer network with a network database. In the case where a computer network with a network database is used as a data concentration device, this results in the advantageous possibility of involving different parts of the network and thus also different databases in the individual check. Flexible overlapping of these areas is also entirely possible.

A telecommunications network in the sense of the invention is any network over which speech and data can be transferred.

The transfer of data between the data communications device and the data concentration device is preferably by parameterized hyperlink.

In the data concentration device, the bid-related data transmitted from the data communications device is evaluated using the data available there and at least one criterion for checking, the price of the offered product playing either no part or a subordinate part.

This bid-related data preferably includes:

a. the material costs, in particular direct material costs, costs for purchased parts and material overhead costs, the material overhead costs preferably being specified as a percentage value in relation to the direct material costs,

b. the production costs, in particular the direct production costs and production overhead costs, the statement of direct production costs preferably including workplace costs in DM/min and cycle times, and the production overhead costs preferably being given as a percentage value, related to the sum of the direct wage costs, sum of the asset values, or the sum of the production costs,

c. the overhead costs, in particular sales overhead and administrative overhead costs, preferably given as a percentage in relation to the production or manufacturing costs,

d. the development costs, in particular development overhead costs and direct development costs, preferably given as a percentage in relation to the production or manufacturing costs,

e. other costs, in particular direct tool costs, direct costs of development, setup costs, packaging costs, freight costs and/or cash discount

f. the profit in relation to material costs, production costs or modules, and/or

g. the sum of a to f.

This bid-related data is compared in each case with the available reference values, so-called benchmarks, in the data concentration device, and thereby checked for whether the bid is reasonable with regard to the material costs, the production costs, the overhead costs, the development costs and/or the other costs. The bid-related data is preferably compared with an average value and with a best value.

If the bid at least matches the average value in all the cost elements named above or furnished with bid data, the order release is effected by the data concentration device preferably in the form of a release code, which references the particular bid and is transmitted to the buyer's data communications device.

If the bid is above the average value, i.e is more expensive than the average, at least in one of the cost elements named above or furnished with bid data, the data concentration device preferably creates a weak-point analysis with regard to the relevant cost element, and if applicable makes suggestions about how these costs can be lowered. This weak-point analysis is preferably transmitted to the buyer's data communications device.

In the case that the bid being evaluated is above the average value for one or more cost elements and/or in the sum of all costs, i.e. is too expensive overall, the acceptance of the bid is preferably made subject to financial conditions, which are automatically determined by the data concentration device and transmitted together with the release code to the buyer's data communications device.

If a bid is fully unacceptable, because it is above the average value in too many cost elements, it is declined by the data concentration device and a fake code referencing the relevant bid is optionally sent from the data concentration device to the buyer's data communications device.

Regardless of whether a bid is accepted or declined, the bid data is saved by the data communications device and consulted each time for calculating new average values for the relevant cost element. If costs for the particular cost element are more favourable than the best value stored in the data communications device, the old best value is discarded and a new best value is stored in the data communications device.

In a preferred embodiment of the method according to the invention, after the transmission of the order number from the data concentration device, an electronic message confirming the order release is also sent to the buyer's email address.

In another preferred embodiment of the method according to the invention, after the transmission of the order number from the data concentration device, an electronic message confirming the order release is also sent to the buyer's fax machine.

The method according to the invention has the advantage that an order release is effected fully automatically, rapidly, and based on objectively traceable criteria. The buyer receives a weak-point analysis of the supplier, and information about how the supplier's costs compare to the competition.

A further subject of the present invention is a method for automated order placement by means of data communications devices, telecommunications networks and at least one data concentration device, the method presenting any number of repetitions of the following procedural steps:

a) Transmission of a bid with data relating to the bid, by means of a data communications device over a telecommunications network to a data concentration device,

b) Evaluation, in the data concentration device, of the bid-related data transmitted in step a), using the data available there and at least one checking criterion,

whereupon in the case of a positive evaluation:

bb1) the order is placed in the form of an order number referencing the particular bid,

bb2) the transmitted data is transferred into the available data in the data concentration device, according to a data acquisition process,

bb3) the order number is transmitted back from the data concentration device over a telecommunications network to the buyer's data communications device,

and whereupon in the case of a negative evaluation:

bb4) the transmitted data is transferred into the available data in the data concentration device, according to a data acquisition process,

bb5) a rejection is optionally sent from the data concentration device over the telecommunications network to the data communications device.

A data communications device in the sense of the invention is any data terminal that has, among others, HTML (HyperText Markup Language) capability; preferably a standard personal computer. On to this data communications device are loaded e.g. home pages from a buyer's server, containing the bid invitation for a particular product. The desired product is specified in detail in the bid invitation, and the bid-related data to be presented by the seller when submitting a bid is also precisely stated. The seller's bid with the bid-related data is also transmitted to the data concentration device from this terminal.

A data concentration device in the sense of the invention is any single database computer, or a computer network with a network database. In the case where a computer network with a network database is used as a data concentration device, this results in the advantageous possibility of involving different parts of the network and thus also different databases in the relevant check. Flexible overlapping of these areas is also entirely possible.

A telecommunications network in the sense of the invention is any network over which speech and data can be transferred.

The transfer of data between the data communications device and the data concentration device is preferably by parameterized hyperlink.

In the data concentration device, the bid-related data transmitted from the data communications device is evaluated using the data available there and at least one criterion for checking, the price of the offered product playing either no part or a subordinate part.

This bid-related data preferably includes:

a. the material costs, in particular direct material costs, costs for purchased parts and material overhead costs, the material overhead costs preferably being specified as a percentage value in relation to the direct material costs,

b. the production costs, in particular the direct production costs and production overhead costs, the statement of direct production costs preferably including workplace costs in DM/min and cycle times, and the production overhead costs preferably being given as a percentage value, related to the sum of the direct wage costs, sum of the asset values, or the sum of the production costs,

c. the overhead costs, in particular sales overhead and administrative overhead costs, preferably given as a percentage in relation to the production or manufacturing costs,

d. the development costs, in particular development overhead costs and direct development costs, preferably given as a percentage in relation to the production or manufacturing costs,

e. other costs, in particular direct tool costs, direct costs of development, setup costs, packaging costs, freight costs and/or cash discount,

f. the profit in relation to material costs, production costs or modules, and/or

g. the sum of a to f.

This bid-related data is compared in each case with the available reference values, so-called benchmarks, in the data concentration device, and thereby checked for whether the bid is reasonable with regard to the material costs, the production costs, the overhead costs, the development costs and/or the other costs. The bid-related data is preferably compared with an average value and with a best value. If the bid at least matches the average value in all the cost elements named above or furnished with bid data, the order placement is effected by the data concentration device preferably in the form of an order number, which is transmitted back to the buyer's data communications device.

If the bid is above the average value at least in one of the cost elements named above or furnished with bid data, i.e. is more expensive, the data concentration device preferably creates a weak-point analysis with regard to the relevant cost element, and if applicable makes suggestions about how these costs can be lowered. This weak-point analysis is preferably transmitted to the data communications device of the supplier and/or the buyer.

In the case that the bid being evaluated is above the average value, i.e. is more expensive, for one or more cost elements and/or in the sum of all costs, the acceptance of the bid is preferably made subject to financial conditions, which are automatically determined by the data concentration device and transmitted together with the order number to the data communications device of the supplier and/or the buyer.

If a bid is fully unacceptable, because it is above the average value in too many cost elements, it is declined by the data concentration device and a rejection is optionally sent from the data concentration device to the data communications device of the supplier and/or the buyer.

Regardless of whether a bid is accepted or declined, the bid data is saved by the data communications device and consulted each time for calculating new average values for the relevant cost element. If costs for the particular cost element are more favourable than the best value stored in the data communications device, the old best value is discarded and a new best value is stored in the data communications device.

In a preferred embodiment of the method according to the invention, after the transmission of the order number from the data concentration device, an electronic message confirming the acceptance is also sent to the supplier's email address.

In another preferred embodiment of the method according to the invention, after the transmission of the order number from the data concentration device, an electronic message confirming the acceptance is also sent to the supplier's fax machine.

The method according to the invention has the advantage that an order placement is effected fully automatically, rapidly, and based on objectively traceable criteria. The supplier and the buyer receive a weak-point analysis, with which the supplier can improve his cost structure, and information about how his costs compare to the competition.

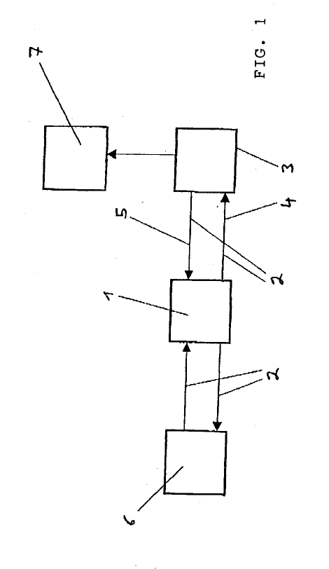

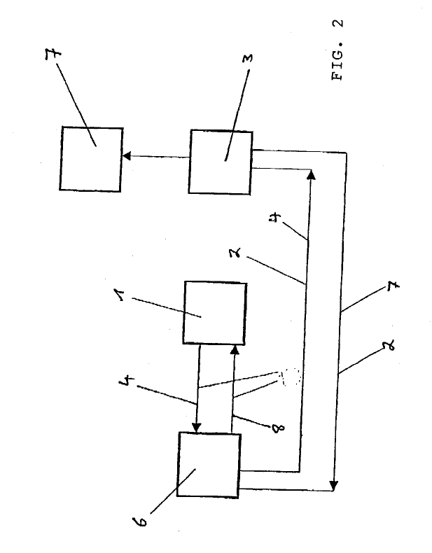

The method according to the invention for automatic order placement is explained below with reference to FIG. 1, and the method for automatic order release with reference to FIG. 2. These illustrations are purely examples, and do not restrict the general idea of the invention.

FIG. 1 shows a method for automatic placing of orders. The supplier uses a personal computer (PC) 1, in order to load the home page of the virtual market on to his PC 1 from the server 6 via the telecommunications network 2. The bid invitation from a buyer appears on this home page. The offer includes a detailed description of the desired products and a precise listing of the desired bid data. In the present example, the bid-related data should cover the following particulars:

a. the material costs, in particular direct material costs, costs for purchased parts and material overhead costs,

b. the production costs, in particular the direct production costs and the production overhead costs and cycle times,

c. the overhead costs, in particular sales overhead and administrative overhead costs,

d. the development costs, in particular development overhead costs and direct development costs,

e. other costs, in particular direct tool costs, packaging, freight, discount

f. the profit and

g. the sum of a to f=the quotation price or sales price.

The bit-related data 4 is transferred by parameterized hyperlink from his PC 1 over the telecommunications network 2 to the computer 3. Several databases are connected to the computer 3. The expert will recognize that the server 6 and the computer 3 can be one device or a computer network.

In the computer 3, with the aid of the databases, the size of each cost element is compared with an average value for the particular cost element, establishing whether the specified costs are above the average value, i.e. are more expensive.

In the present example, only the production costs are more expensive than the average value. From the figures given for the cycle times specified in the bid, the computer 3 can find out that these are higher than the industry average.

After the evaluation, the computer 3 transfers the transmitted bid data into one of the connected databases with a data transfer procedure, and returns an order number and a weak-point analysis to the PC 1 and PC 6 via the telecommunications network 2. The weak-point analysis shows the supplier that his cycle times are too long. In this case the order placement is made subject to the condition that the production costs may at most be equal to the average value.

At the same time an email containing the essential terms and conditions of the order is stored on an email server 7. There is similarly a telecommunications network connection (not shown) between the email server 7 and the PC 1 and PC 6.

FIG. 2 shows a method for automatic order release. The supplier uses a personal computer (PC) 1, in order to load the buyer's home page from the server 6 over the telecommunications network 2 on to his PC 1. The bid invitation from a buyer appears on this home page. The offer includes a detailed description of the desired products and a precise listing of the desired bid data.

In the present example, the bid-related data should cover the following particulars:

a. the material costs, in particular direct material costs, costs for purchased parts and material overhead costs,

b. the production costs, in particular the direct production costs and the production overhead costs and cycle times,

c. the overhead costs, in particular sales overhead and administrative overhead costs,

d. the development costs, in particular development overhead costs and direct development costs,

e. other costs, in particular direct tool costs, packaging, freight, discount

f. the profit

The bit-related data 4 is transferred by parameterized hyperlink from his PC 1 over the telecommunications network 2 to the computer 6 and from there to PC 3. Several databases are connected to the computer 3. The expert will recognize that the server 6 and the computer 3 can be one device or a computer network.

In the computer 3, with the aid of the databases, the size of each cost element is compared with an average value for the particular cost element, establishing whether the specified costs are above the average value.

In the present example, only the production costs are more expensive than the average value. From the figures given for the cycle times specified in the bid, the computer 3 can find out that these are higher than the industry average.

After the evaluation, the computer 3 transfers the transmitted bid data into one of the connected databases with a data transfer procedure, and sends a release code 7 referencing the particular bid, with a weak-point analysis, to the PC 6 via the telecommunications network 2. The weak-point analysis shows the buyer that the supplier's cycle times are too long. In this case the order placement is made subject to the condition that the production costs may at most be equal to the average value.

At the same time an email containing the essential terms and conditions of the order is stored on an email server 7. There is similarly a telecommunications network connection (not shown) between the email server 7 and the PC 6.

The order release 8 is then finally transmitted from the PC 6 to PC 1.

1. Method for automated order release by means of data communications devices (1), telecommunications networks (2) and at least one data concentration device (3), the method presenting any number of repetitions of the following procedural steps:
a) Transmission of a bid with bid-related data (4) by means of a data communications device (1) over a telecommunications network (2) to a data concentration device (3),
b) Evaluation, in the data concentration device (3), of the bid-related data (4) transmitted in step a), using the data available there and at least one checking criterion,
whereupon in the case of a positive evaluation:
bb1) the order release follows in the form of a release code (5) referencing the particular bid,
bb2) the transmitted data (4) is transferred into the available data in the data concentration device (3), according to a data acquisition process,
bb3) the release code (5) is transmitted from the data concentration device (3) over a telecommunications network (2) to the data communications device (6),
and whereupon in the case of a negative evaluation:
bb4) the transmitted data (4) is transferred into the available data in the data concentration device (3), according to a data acquisition process,
bb5) a fake code referencing the relevant bid is optionally sent from the data concentration device (3) over the telecommunications network (2) to the data communications device (6).

2. Method as claimed in claim 1, characterized in that as bid-related data:
a. the material costs, in particular direct material costs, costs for purchased parts and material overhead costs,
b. the production costs, in particular the direct production costs and the production overhead costs,
c. the overhead costs, in particular sales overhead and administrative overhead costs,
d. the development costs, in particular development overhead costs and direct development costs,
e. other costs, in particular direct tool costs,
f. profit and/or
g. the sum of a to f
are evaluated.

3. Method as claimed in claim 1 or 2, characterized in that an examination of reference values; preferably separately for each of the items a to f, is undertaken as the checking criterion.

4. Method as claimed in one of claims 1 to 3, characterized in that the result of the evaluation of the bid-related data is transmitted with a weak-point analysis to the data communications device (6).

5. Method as claimed in one of claims 1 to 4, characterized in that the transferred data is consulted by the data concentration device for the respective calculation of new reference values, preferably for the calculation of average or best values.

6. Method as claimed in claim 1-5, characterized in that the data concentration device determines financial conditions for the order placement, which are transmitted with the bid release to the data communications device (6).

7. Method as claimed in claim 1 to 6, characterized in that for a bid release, an electronic message confirming the bid release is additionally automatically sent from the data concentration device (3) over a telecommunications network (2) to the buyer's email address.

8. Method as claimed in claim 1 to 6, characterized in that for a bid release, an electronic message confirming the bid release is additionally automatically sent from the data concentration device (3) over a telecommunications network (2) to the buyer's fax machine.

9. Method for automated order placement by means of data communications devices (1), telecommunications networks (2) and at least one data concentration device (3), the method presenting any number of repetitions of the following procedural steps:
a) Transmission of a bid with bid-related data (4) by means of a data communications device (1) over a telecommunications network (2) to a data concentration device (3),
b) Evaluation, in the data concentration device (3), of the bid-related data (4) transmitted in step a), using the data available there and at least one checking criterion,
whereupon in the case of a positive evaluation:
bb1) the order placement follows in the form of an order number (5) referencing the particular bid,
bb2) the transmitted data (4) is transferred into the available data in the data concentration device (3), according to a data acquisition process,
bb3) the order number (5) is transmitted back from the data concentration device (3) over a telecommunications network (2) to the data communications device (1),
and whereupon in the case of a negative evaluation:
bb4) the transmitted data (4) is transferred into the available data in the data concentration device (3), according to a data acquisition process,
bb5) a rejection is optionally sent from the data concentration device (3) over the telecommunications network (2) to the data communications device (1).

10. Method as claimed in claim 9, characterized in that as bid-related data:
a. the material costs, in particular direct material costs, costs for purchased parts and material overhead costs,
b. the production costs, in particular the direct production costs and the production overhead costs,
c. the overhead costs, in particular sales overhead and administrative overhead costs,
d. the development costs, in particular development overhead costs and direct development costs,
e. other costs, in particular direct tool costs,
f. the profit and/or
g. the sum of a to f
are evaluated.

11. Method as claimed in claim 9 or 10, characterized in that an examination of reference values, preferably separately for each of the items a to f, is undertaken as the checking criterion.

12. Method as claimed in one of claims 9 to 11, characterized in that the result of the evaluation of the bid-related data is transmitted back with a weak-point analysis to the data communications device (1).

13. Method as claimed in one of claims 9 to 12, characterized in that the transferred data is consulted by the data concentration device for the respective calculation of new reference values, preferably for the calculation of average or best values.

14. Method as claimed in claim 9 to 13, characterized in that the data concentration device determines financial conditions for the order placement, which are transmitted back with the order placement to the data communications device (1).

15. Method as claimed in claim 9 to 14, characterized in that for an order placement, an electronic message confirming the acceptance of the bid is additionally automatically sent from the data concentration device (3) over a telecommunications network (2) to the supplier's email address.

16. Method as claimed in claim 9 to 14, characterized in that for an order placement, an electronic message confirming the acceptance of the bid is additionally automatically sent from the data concentration device (3) over a telecommunications network (2) to the supplier's fax machine.

17. Method as claimed in one of claims 1 to 16, characterized in that the data is transmitted between the data communications device (1, 6) and the data concentration device (3) by parameterized hyperlink.
